(19) United States
(12) Patent Application Publication
(10) Pub. No.: US 2025/0098195 A1
(43) Pub. Date: Mar. 20, 2025

(54) IMPURITY REDUCTION TECHNIQUES IN GALLIUM NITRIDE REGROWTH

(71) Applicant: Analog Devices, Inc., Wilmington, MA (US)

(72) Inventors: James G. Fiorenza, Carlisle, MA (US); Daniel Piedra, Somerville, MA (US)

(21) Appl. No.: 18/291,799

(22) PCT Filed: Aug. 3, 2021
(86) PCT No.: PCT/US2021/044355

§ 371 Date: Jan. 24, 2024

(51) Int. Cl. H01L 29/66; H01L 21/324; H01L 29/778

(52) U.S. Cl. CPC H10D 30/015; H01L 21/3245; H10D 30/475

(57) ABSTRACT

Various techniques for impurity dopant reduction in GaN regrowth are described. In a first technique, a barrier layer, such as AlN, can be formed at a regrowth interface before the regrown GaN layer. The barrier layer can bury the impurities at the regrowth interface and reduce their effect on the layers above that include the channel of the device, e.g., transistor. In a second technique, a buffer layer, such as a carbon-doped GaN layer, can be formed at the regrowth interface before the regrown GaN layer. Carbon can act as an acceptor to compensate for the dopants. e.g., silicon, and cancel their electronic effect on the above layers. In a third technique, a hydrogen bake treatment can be performed before the GaN regrowth. Hydrogen can desorb a thin layer of GaN at the regrowth interface, which is the GaN layer with the highest concentration of impurities.

### STATEMENT REGARDING FEDERALLY SPONSORED RESEARCH OR DEVELOPMENT

This invention was made with government support under Grant No. HR0011-18-3-0014 awarded by the Defense Advanced Research Projects Agency (DARPA). The government has certain rights in the invention.

### FIELD OF THE DISCLOSURE

This document pertains generally, but not by way of limitation, to semiconductor devices, and more particularly, to techniques for constructing gallium nitride devices.

### BACKGROUND

Gallium nitride based semiconductors offer several advantages over other semiconductors as the material of choice for fabricating the next generation of transistors, or semiconductor devices, for use in both high-voltage and high-frequency applications. Gallium nitride (GaN) based semiconductors, for example, have a wide-bandgap that enable devices fabricated from these materials to have a high breakdown electric field and to be robust to a wide range of temperatures. The two-dimensional electron gas (2DEG) channels formed by GaN based heterostructures generally have high electron mobility, making devices fabricated using these structures useful in power-switching and amplification systems. GaN based semiconductors, however, are typically used to fabricate depletion mode (or normally on) devices, which can have limited use in many of these systems, such as due to the added circuit complexity required to support such devices.

### SUMMARY OF THE DISCLOSURE

This disclosure describes various techniques for impurity dopant reduction in GaN regrowth. In a first technique, a barrier layer, such as AlN, can be formed at a regrowth interface before the regrown GaN layer. The barrier layer can bury the impurities at the regrowth interface and reduce their effect on the layers above that include the channel of the device, e.g., transistor. In a second technique, a buffer layer, such as a carbon-doped GaN layer, can be formed at the regrowth interface before the regrown GaN layer. Carbon can act as an acceptor to compensate for the dopants, e.g., silicon, and cancel their electronic effect on the above layers. In a third technique, a hydrogen bake treatment can be performed before the GaN regrowth. Hydrogen can desorb a thin layer of GaN at the regrowth interface, which is the GaN layer with the highest concentration of impurities.

In some aspects, this disclosure is directed to a method of forming a semiconductor device to reduce or counteract impurities at a regrowth interface, the method comprising: forming a first semiconductor growth region, including: forming a first buffer layer of a first compound semiconductor material on a substrate; forming a first channel layer with the first buffer layer; forming a first barrier layer with the channel layer thereby forming a first heterostructure, the first heterostructure configured to form a first two-dimensional electron gas (2DEG) channel; reducing or counteracting impurities at the regrowth interface; and forming a second semiconductor growth region at the regrowth interface, including: forming a second heterostructure with the first semiconductor growth region, the second heterostructure configured to form a second 2DEG channel and comprising a second channel layer; and forming first and second spaced apart contact materials coupled to the second channel layer.

In some aspects, this disclosure is directed to a semiconductor assembly comprising: a first semiconductor growth region including: a first heterostructure configured to form a first two-dimensional electron gas (2DEG) channel, the first heterostructure including a first barrier layer formed with a first channel layer; a second semiconductor growth region formed with the first semiconductor growth region at a regrowth interface, the second semiconductor growth region including: a second heterostructure configured to form a second 2DEG channel, the second heterostructure including a second channel layer formed with the first semiconductor growth region; a second barrier layer formed with the first barrier layer at the regrowth interface; and first and second spaced apart contact materials coupled to the second channel layer.

In some aspects, this disclosure is directed to a semiconductor assembly comprising: a first semiconductor growth region including: first heterostructure configured to form a first two-dimensional electron gas (2DEG) channel, the first heterostructure including a first barrier layer formed with a first channel layer; a second semiconductor growth region formed with the first semiconductor growth region at a regrowth interface, the second semiconductor growth region including: a second heterostructure configured to form a second 2DEG channel, the second heterostructure including a second channel layer formed with the first semiconductor growth region; a buffer barrier layer formed with the first barrier layer at the regrowth interface; and first and second spaced apart contact materials coupled to the second channel layer.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a cross-sectional view of an example of a semiconductor assembly in accordance with various techniques of this disclosure.

FIG. 2 is a cross-sectional view of the semiconductor assembly in FIG. 1 with contacts formed.

FIG. 3 is a cross-sectional view of another example of a semiconductor assembly in accordance with various techniques of this disclosure.

FIG. 4 is a cross-sectional view of the semiconductor assembly in FIG. 3 with contacts formed.

FIG. 5 is a cross-sectional view of another example of a semiconductor assembly in accordance with various techniques of this disclosure.

FIG. 6 is a cross-sectional view of the semiconductor assembly of FIG. 5 following a hydrogen bake treatment and regrowth.

FIG. 7 is a cross-sectional view of the semiconductor assembly in FIG. 6 with contacts formed.

### DETAILED DESCRIPTION

Gallium nitride (GaN) semiconductors offer several advantages over other semiconductors as the material of choice for fabricating the next generation of transistors, or semiconductor devices, for use in both high-voltage and high-frequency applications. During semiconductor fabrication, regrowth of GaN by metalorganic chemical vapor deposition (MOCVD) can be a useful process step for several applications, such as for implementing backside field plate techniques. Backside field plates can act as a region to shape and control the electric field from underneath a transistor, for example.

GaN MOCVD regrowth, however, can be accompanied by incorporation of impurity dopants, such as silicon (Si), in the regrown film at the regrowth interface. The undesired impurity dopants present in the regrown film can become incorporated into the GaN and reduce the resistance of the GaN and introduce potential leakage paths. In other words, there can be unwanted surface contamination at the regrowth interface that can contribute unwanted charge and form leakage current in the device, e.g., transistor.

Controlled regrowth of high-quality, low-doped GaN layers can be required in scenarios where a patterned buried epitaxial layer is present, and the buried layer needs to be well isolated from the upper layers. Two relevant scenarios use an aluminum nitride (AlN) layer or aluminum gallium nitride (AlGaN) layer as an epitaxial buried field plate and use a buried AlN as a layer to deplete the GaN channel for enhancement mode operation (or normally off). Thus, it is desirable to reduce the impurity levels at the regrowth interface or negate their doping effects.

This disclosure describes various techniques for impurity dopant reduction in GaN regrowth. In a first technique, a barrier layer, such as AlN, can be formed at a regrowth interface before the regrown GaN layer. The barrier layer can bury the impurities at the regrowth interface and reduce their effect on the layers above that include the channel of the device, e.g., transistor. In a second technique, a buffer layer, such as a carbon-doped GaN layer, can be formed at the regrowth interface before the regrown GaN layer. Carbon can act as an acceptor to compensate for the dopants. e.g., silicon, and cancel their electronic effect on the above layers. In a third technique, a hydrogen bake treatment can be performed before the GaN regrowth. Hydrogen can desorb a thin layer of GaN at the regrowth interface, which is the GaN layer with the highest concentration of impurities. These techniques are described in detail below.

As used in this disclosure, a GaN-based compound semiconductor material can include a chemical compound of elements including GaN and one or more elements from different groups in the periodic table. Such chemical compounds can include a pairing of elements from group 13 (i.e., the group comprising boron (B), aluminum (Al), gallium (Ga), indium (In), and thallium (Tl)) with elements from group 15 (i.e., the group comprising nitrogen (N), phosphorus (P), arsenic (As), antimony (Sb), and bismuth (Bi)). Group 13 of the periodic table can also be referred to as Group III and group 15 as Group V. In an example, a semiconductor device can be fabricated from GaN and aluminum indium gallium nitride (AlInGaN).

Heterostructures described herein can be formed as AlN/GaN/AlN hetero-structures, InAlN/GaN heterostructures, AlGaN/GaN heterostructures, or heterostructures formed from other combinations of group 13 and group 15 elements. These heterostructures can form a two-dimensional electron gas (2DEG) at the interface of the compound semiconductors that form the heterostructure, such as the interface of GaN and AlGaN. The 2DEG can form a conductive channel of electrons that can be controllably depleted, such as by an electric field formed by a buried layer of p-type material disposed below the channel. The conductive channel of electrons that can also be controllably enhanced, such as by an electric field formed by a gate terminal disposed above the channel to control a current through the semiconductor device. Semiconductor devices formed using such conductive channels can include high electron mobility transistors.

FIG. 1 is a cross-sectional view of an example of a semiconductor assembly in accordance with various techniques of this disclosure. In particular, FIG. 1 depicts the first technique for impurity dopant reduction in GaN regrowth in which a barrier layer, such as AlN, can be formed at the regrowth interface before the regrown GaN laver. The assembly 100 of FIG. 1 can include a first semiconductor growth region 102 (or original growth) and a second semiconductor growth region 104 (or regrowth) formed at a regrowth interface that is the top-most portion of the first semiconductor growth region 102.

The first semiconductor growth region 102 can include a substrate 106, such as sapphire, silicon (Si), or silicon carbide (SiC). Next, a first buffer layer 108 of a first compound semiconductor material, such as a carbon-doped GaN layer, can be formed on the substrate 106. In some examples, the first buffer layer 108 can be formed on the substrate 106 by depositing the first buffer layer 108 directly on the substrate 106. In other examples, the first buffer layer 108 can be formed on the substrate 106 by depositing the first buffer layer 108 suprajacent the substrate 106 with an intervening layer 110, such as an AlN seed layer, formed between the first buffer layer 108 and the substrate 106.

A first channel layer 112. e.g., a GaN channel layer, can be formed with the first buffer layer 108. A first barrier layer 114 of a first semiconductor material, e.g., AlN or AlGaN, can be formed superjacent the first channel layer 112, thereby forming a first heterostructure. The first heterostructure is configured to form a first two-dimensional electron gas (2DEG) channel, as represented by the dashed line in the first channel layer 112. In some examples, the first barrier layer 114 can be AlN and have a thickness of about 4-6 nanometers (nm). In some examples, the first barrier 114 can be AlGaN and have a thickness of about 15-30 nm

The top of the first barrier layer 114 represents the regrowth interface. In accordance with this disclosure, rather than regrow a second channel layer directly on the first barrier layer 114, a second barrier layer 116 of a second semiconductor material, e.g., AlN or AlGaN, can be formed after the original growth with the first barrier layer 114 to reduce or counteract impurities at the regrowth interface. Without being bound by theory, the second barrier layer 116 may bury the silicon at the regrowth interface and reduce or eliminate its influence on the second 2DEG channel in the second channel layer. In some examples, the second barrier layer 116 can have a thickness of about 2 nm.

In some implementations, the first and second semiconductor materials can include the same semiconductor material. For example, both the first and second semiconductor materials can include AlN. In some implementations, at least one of the first semiconductor material and the second semiconductor material can include aluminum nitride. Example combinations of the first and second semiconductor materials can include AlN/AlN, AlN/AlGaN, and AlGaN/AlN.

The second semiconductor growth region 104 can include the second barrier layer 116 and can be formed with the first semiconductor growth region 102 at the regrowth interface. The second semiconductor growth region 104 can include a second heterostructure formed with the first semiconductor growth region. The second heterostructure can include a second channel layer 118 formed with the first barrier layer 114 and a third barrier layer 120, such as AlGaN, formed superjacent the second channel layer 118. In some examples, the third barrier layer can be about 23 nm. The second heterostructure is configured to form a second 2DEG channel, as represented by the dashed line in the second channel layer 118.

A layer 122 of silicon nitride (SiN) can be formed with the third barrier layer. Isolation implants 122A, 122B can isolate the first (bottom) 2DEG channel from interacting with the second (top) 2DEG channel through the sides of the assembly 100.

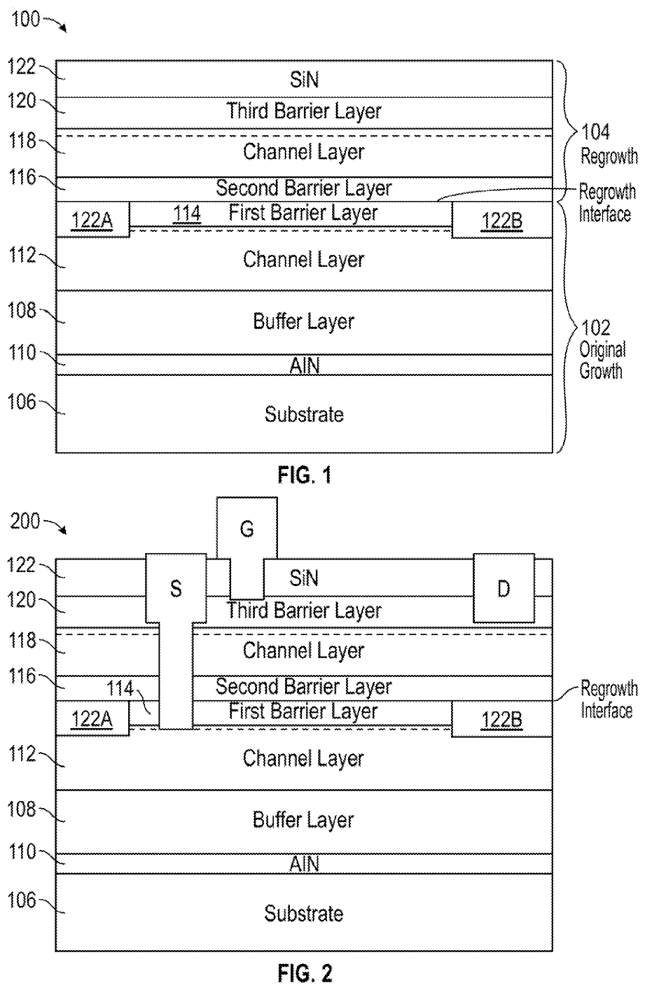

FIG. 2 is a cross-sectional view of the semiconductor assembly in FIG. 1 with contacts formed. In particular, the assembly 200 of FIG. 2 depicts the drain (D) and source(S) ohmic contacts and the gate (G) contacts of a transistor assembly. The gate contact material is etched into a region formed within the layer 122. The drain and source contacts include laterally spaced apart contact material and are coupled to the second channel layer 118. In some examples, the drain contact can be coupled to the second channel layer 118 by extending down toward the 2EG channel, where the depth can be a design parameter. In some examples, the drain contact can be coupled to the second channel layer 118 such that the drain contact is slightly above the 2DEG channel, with a small thickness of barrier remaining, which can provide a lower contact resistance than having the drain contact extend all the way down to the second channel layer.

In addition, the source contact can be coupled to the first channel layer 112. Additional dielectric material can be deposited over the layer 122, for example.

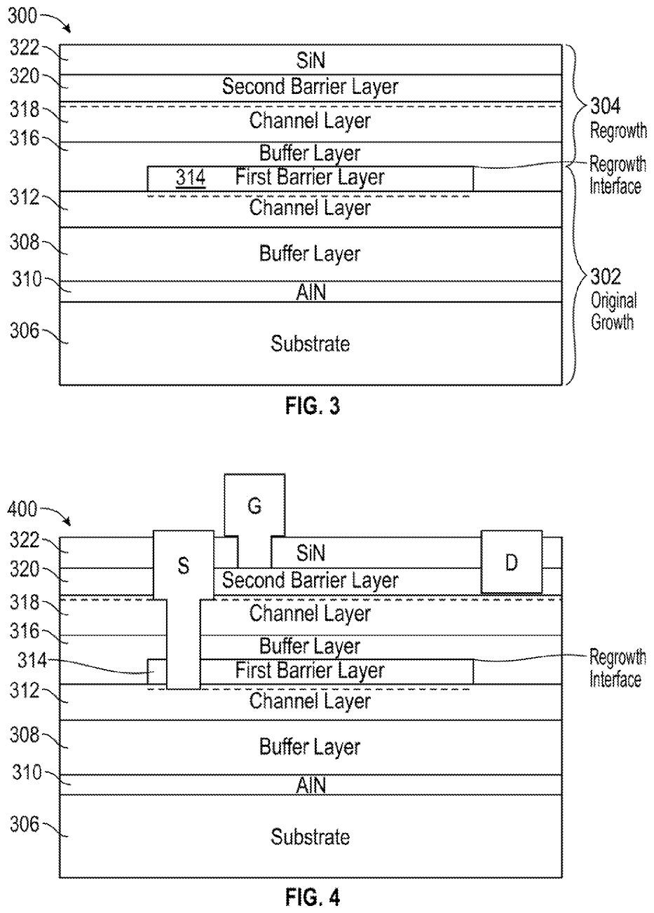

As mentioned above, in a second technique for impurity dopant reduction in GaN regrowth, a buffer layer, such as a carbon-doped GaN layer, can be formed at the regrowth interface before the regrown GaN layer, which is shown and described below with respect to FIGS. 3 and 4.

FIG. 3 is a cross-sectional view of another example of a semiconductor assembly in accordance with various techniques of this disclosure. In particular. FIG. 3 depicts the second technique for impurity dopant reduction in GaN regrowth in which a buffer layer, such as carbon-doped GaN, can be formed at the regrowth interface before the regrown GaN layer. Carbon can act as an acceptor to compensate for the dopants, e.g., silicon, and cancel their electronic effect on the above layers. The assembly 300 of FIG. 3 can include a first semiconductor growth region 302 (or original growth) and a second semiconductor growth region 304 (or regrowth) formed at a regrowth interface, which is the top-most portion of the first semiconductor growth region 302.

The first semiconductor growth region 302 can include a substrate 306, such as sapphire, silicon (Si), or silicon carbide (SIC). Next, a first buffer layer 308 of a first compound semiconductor material, such as a carbon-doped GaN layer, can be formed on the substrate 306. In some examples, the first buffer layer 308 can be formed on the substrate 306 by depositing the first buffer layer 308 directly on the substrate 306. In other examples, the first buffer layer 308 can be formed on the substrate 306 by depositing the first buffer layer 308 suprajacent the substrate 306 with an intervening layer 310, such as AlN, formed between the first buffer layer 308 and the substrate 306.

A first channel layer 312, e.g., a GaN channel layer, can be formed with the first buffer layer 308. A first barrier layer 314 of a first semiconductor material, e.g., AlN or AlGaN, can be formed superjacent the first channel layer 312, thereby forming a first heterostructure. The first heterostructure is configured to form a first two-dimensional electron gas (2DEG) channel, as represented by the dashed line in the first channel layer 312. In some examples, the first barrier layer 314 can have a thickness of about 4 nm.

The top of the first barrier layer 314 represents the regrowth interface. In accordance with this disclosure, rather than regrow a second channel layer directly on the first barrier layer 314, a second buffer layer 316 of a second semiconductor material can be formed (such as after the original growth) with the first barrier layer 314 to reduce or counteract impurities at the regrowth interface.

Without being bound by theory, the second buffer layer 316 may counter-dope the impurities, e.g., Si, at the regrowth interface and reduce or eliminate their influence on the second 2DEG channel in the second channel layer. The second buffer layer 316 can counteract the effect of the Si so that there are no activated dopants to cause the leakage current.

In some examples, the second buffer layer 316 can be carbon-doped GaN, such as with a carbon doping concentration of about 2e19 cm⁻³, for example. In contrast, the first buffer layer 308 can have a carbon doping concentration in the range of high ×10¹⁷ cm⁻³ to high ×10¹⁸ cm⁻³. In some examples, the second buffer layer 316 can have a thickness of between about 5 nm and about 10 nm, such as about 7.5 nm. In some examples, the second buffer layer 316 can have a thickness less than the first buffer layer 308.

As seen in the example in FIG. 3, the first barrier layer 314 has been etched away such that it does not extend over the entire width of the first channel layer 312. In such a configuration, there is no backside field plate in the regions where the first barrier layer 314 has been etched away.

The second semiconductor growth region 304 can include the second buffer layer 316 and can be formed with the first semiconductor growth region 102 at the regrowth interface. The second semiconductor growth region 304 can include a second heterostructure formed with the first semiconductor growth region. The second heterostructure can include a second channel layer 318 formed with the second buffer layer 316 and a second barrier layer 320, such as AlGaN, formed superjacent the second channel layer 318. In some examples, the second barrier layer 320 can be about 23 nm. The second heterostructure is configured to form a second 2DEG channel, as represented by the dashed line in the second channel layer 318. A layer 322 of silicon nitride (SiN) can be formed with the second barrier layer 320. In some examples, the layer 322 of SiN can be about 20 nm.

FIG. 4 is a cross-sectional view of the semiconductor assembly in FIG. 3 with contacts formed. In particular, the assembly 400 of FIG. 2 depicts the drain (D) and source(S) ohmic contacts and the gate (G) contacts of a transistor assembly. The gate contact material is etched into a region formed within the layer 322. The drain and source contacts include laterally spaced apart contact material and are connected to the second channel layer 318. In addition, the source contact extends to the first channel layer 312. Additional dielectric material can be deposited over the layer 322, for example.

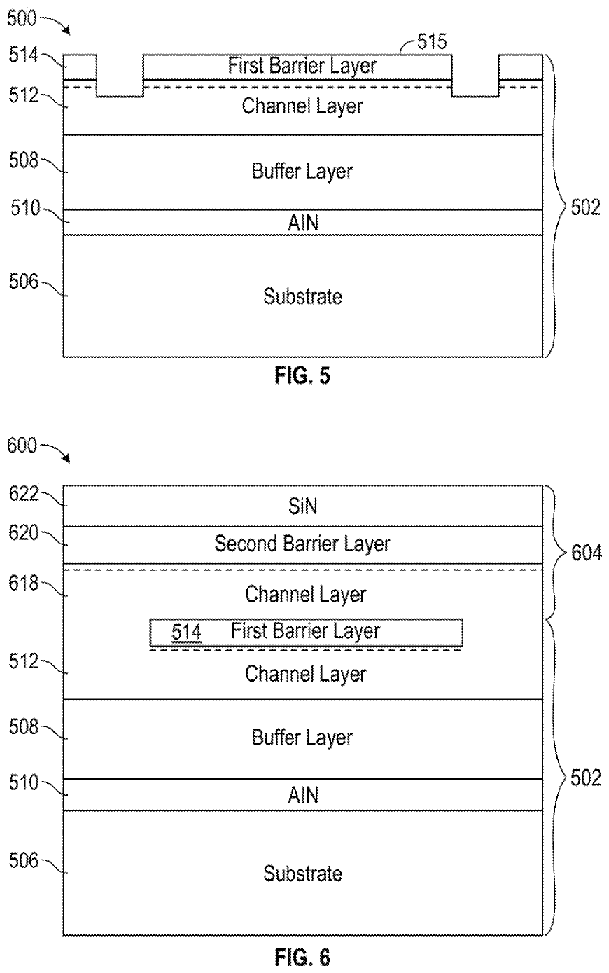

As mentioned above, in a third technique for impurity dopant reduction in GaN regrowth, a hydrogen bake step can occur before the GaN regrowth. Hydrogen can desorb a thin layer of GaN at the regrowth interface, which is the GaN layer with the highest concentration of impurities. The third technique is shown and described below with respect to FIGS. 5-7.

FIG. 5 is a cross-sectional view of another example of a semiconductor assembly in accordance with various techniques of this disclosure. In particular, FIG. 5 depicts the third technique for impurity dopant reduction in GaN regrowth in which a hydrogen bake step can occur before the GaN regrowth. The assembly 500 of FIG. 5 can include a first semiconductor growth region 502 (or original growth).

The first semiconductor growth region 502 can include a substrate 506, such as sapphire, silicon (Si), or silicon carbide (SIC). Next, a first buffer layer 508 of a first compound semiconductor material, such as a carbon-doped GaN layer, can be formed on the substrate 506. In some examples, the first buffer layer 508 can be formed on the substrate 506 by depositing the first buffer layer 508 directly on the substrate 506. In other examples, the first buffer layer 508 can be formed on the substrate 506 by depositing the first buffer layer 508 suprajacent the substrate 506 with an intervening layer 510, such as AlN, formed between the first buffer layer 508 and the substrate 506.

A first channel layer 512, e.g., a GaN channel layer, can be formed with the first buffer layer 508. A first barrier layer 514 of a first semiconductor material, e.g., AlN or AlGaN, can be formed superjacent the first channel layer 512, thereby forming a first heterostructure. The first heterostructure is configured to form a first two-dimensional electron gas (2DEG) channel, as represented by the dashed line in the first channel layer 512. In some examples, the first barrier layer 514 can have a thickness of about 4 nm.

Next, a hydrogen bake treatment can be performed on the assembly 500 before forming a second semiconductor growth region to reduce the impurities at the regrowth interface. The hydrogen bake treatment can include exposing the original growth of assembly 500, which includes the impurities, such as Si, to a high temperature hydrogen atmosphere to reduce the level of impurities at the regrowth interface 515. The hydrogen bake treatment can be long enough to remove the surface impurities but short enough that the treatment does not etch away too much of any exposed GaN. In an example, the hydrogen bake can occur for about 30 seconds to about 5 minutes at a temperature of about 800 degrees Celsius to about 1100 degrees Celsius at a pressure of about 100 millibars to about 500 millibars.

FIG. 6 is a cross-sectional view of the semiconductor assembly of FIG. 5 following a hydrogen bake treatment and regrowth. The assembly 600 of FIG. 6 can include a second semiconductor growth region 604 (or regrowth).

The second semiconductor growth region 604 can include a second heterostructure formed with the first semiconductor growth region. The second heterostructure can include a second channel layer 618 formed with the first barrier layer 514 and a second barrier layer 620, such as AlGaN, formed superjacent the second channel layer 618. In some examples, the second barrier layer 620 can be about 23 nm. The second heterostructure is configured to form a second 2DEG channel, as represented by the dashed line in the second channel layer 618. A layer 622 of silicon nitride (SiN) can be formed with the second barrier layer 620. In some examples, the layer 622 of SiN can be about 20 nm.

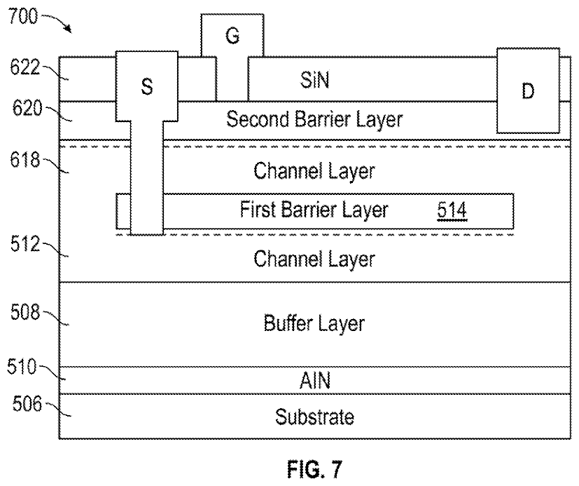

FIG. 7 is a cross-sectional view of the semiconductor assembly in FIG. 6 with contacts formed. In particular, the assembly 700 of FIG. 7 depicts the drain (D) and source(S) ohmic contacts and the gate (G) contacts of a transistor assembly. The gate contact material is etched into a region formed within the layer 622. The drain and source contacts include laterally spaced apart contact material and are connected to the second channel layer 618. In addition, the source contact extends to the first channel layer 512. Additional dielectric material can be deposited over the layer 622, for example.

The techniques described above can reduce or overcome the problem of undesired impurity dopants, such as silicon, being present in the regrown film. The techniques presented above can reduce or overcome this problem by: (i) growing an interlayer to block the effect of the impurity dopant at the regrowth interface; (ii) growing a layer, such as a carbon-doped GaN layer, to compensate for the impurity dopant; or (iii) performing a hydrogen bake treatment to desorb a thin layer of GaN and remove the impurity dopant.

### Various Notes

Each of the non-limiting aspects or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B.” “B but not A,” and “A and B.” unless otherwise indicated. In this document, the terms “including” and “in which” are used as the plain-English equivalents of the respective terms “comprising” and “wherein.” Also, in the following aspects, the terms “including” and “comprising” are open-ended, that is, a system, device, article, composition, formulation, or process that includes elements in addition to those listed after such a term in a aspect are still deemed to fall within the scope of that aspect. Moreover, in the following aspects, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the aspects. Also, in the above Detailed Description, various features may be grouped together to streamline the disclosure. This should not be interpreted as intending that an unclaimed disclosed feature is essential to any aspect. Rather, inventive subject matter may lie in less than all features of a particular disclosed embodiment. Thus, the following aspects are hereby incorporated into the Detailed Description as examples or embodiments, with each aspect standing on its own as a separate embodiment, and it is contemplated that such embodiments may be combined with each other in various combinations or permutations. The scope of the invention should be determined with reference to the appended aspects, along with the full scope of equivalents to which such aspects are entitled.

1. A method of forming a semiconductor device to reduce or counteract impurities at a regrowth interface, the method comprising:
forming a first semiconductor growth region, including:
forming a first buffer layer of a first compound semiconductor material on a substrate;
forming a first channel layer with the first buffer layer;
forming a first barrier layer with the first channel layer thereby forming a first heterostructure, the first heterostructure configured to form a first two-dimensional electron gas (2DEG) channel;
reducing or counteracting impurities at the regrowth interface; and
forming a second semiconductor growth region at the regrowth interface, including:
forming a second heterostructure with the first semiconductor growth region, the second heterostructure configured to form a second 2DEG channel and comprising a second channel layer; and
forming first and second spaced apart contact materials coupled to the second channel layer.

2. The method of claim 1, wherein reducing or counteracting impurities at the regrowth interface comprises:
forming a second barrier layer with the first barrier layer, wherein the second barrier layer has a thickness less than a thickness of the first barrier layer.

3. The method of claim 2, wherein the first barrier layer includes a first semiconductor material, and wherein the second barrier layer includes a second semiconductor material.

4. The method of claim 3, wherein the first and second semiconductor materials include the same semiconductor material.

5. The method of claim 4, wherein the first and second semiconductor materials include aluminum nitride.

6. The method of claim 3, wherein at least one of the first semiconductor material and the second semiconductor material includes aluminum nitride.

7. The method of claim 1, wherein reducing or counteracting impurities at the regrowth interface comprises:
forming a second buffer layer with the first barrier layer.

8. The method of claim 7, wherein forming the second buffer layer with the first barrier layer includes:
forming a carbon-doped gallium nitride buffer layer with the first barrier layer.

9. The method of claim 1, wherein reducing or counteracting impurities at the regrowth interface comprises:
performing a hydrogen bake treatment before forming the second semiconductor growth region to reduce the impurities at the regrowth interface.

10. The method of claim 1, wherein forming the first buffer layer of the first compound semiconductor material on the substrate includes:
forming the first buffer layer suprajacent the substrate with an intervening layer formed between the first buffer layer and the substrate.

11. A semiconductor assembly comprising:
a first semiconductor growth region including:
a first heterostructure configured to form a first two-dimensional electron gas (2DEG) channel, the first heterostructure including a first barrier layer formed with a first channel layer;
a second semiconductor growth region formed with the first semiconductor growth region at a regrowth interface, the second semiconductor growth region including:
a second heterostructure configured to form a second 2DEG channel, the second heterostructure including a second channel layer formed with the first semiconductor growth region;
a second barrier layer formed with the first barrier layer at the regrowth interface; and
first and second spaced apart contact materials coupled to the second channel layer.

12. The semiconductor assembly of claim 11, wherein the second barrier layer has a thickness less than a thickness of the first barrier layer.

13. The semiconductor assembly of claim 11, wherein the first barrier layer includes a first semiconductor material, and wherein the second barrier layer includes a second semiconductor material.

14. The semiconductor assembly of claim 13, wherein the first and second semiconductor materials include the same semiconductor material.

15. The semiconductor assembly of claim 14, wherein the first and second semiconductor materials include aluminum nitride.

16. The semiconductor assembly of claim 13, wherein at least one of the first semiconductor material and the second semiconductor material includes aluminum nitride.

17. A semiconductor assembly comprising:
a first semiconductor growth region including:
a first heterostructure configured to form a first two-dimensional electron gas (2DEG) channel, the first heterostructure including a first barrier layer formed with a first channel layer;
a second semiconductor growth region formed with the first semiconductor growth region at a regrowth interface, the second semiconductor growth region including:
a second heterostructure configured to form a second 2DEG channel, the second heterostructure including a second channel layer formed with the first semiconductor growth region;
a buffer layer formed with the first barrier layer at the regrowth interface; and
first and second spaced apart contact materials coupled to the second channel layer.

18. The semiconductor assembly of claim 17, wherein the buffer layer includes a carbon-doped gallium nitride buffer layer.

19. The semiconductor assembly of claim 18, wherein buffer layer has a thickness of between about 5 nanometers and about 10 nanometers.

20. The semiconductor assembly of claim 17, wherein the first barrier layer includes aluminum nitride.
